(19) United States
(12) Patent Application Publication
(10) Pub. No.: US 2024/0282250 A1
(43) Pub. Date: Aug. 22, 2024

(54) DISPLAY PANEL AND DISPLAY APPARATUS

(71) Applicant: Chengdu Vistar Optoelectronics Co., Ltd., Chengdu (CN)

(72) Inventors: Shan GAO, Chengdu (CN); Wen TAN, Chengdu (CN); Yisuei LIAO, Chengdu (CN)

(73) Assignee: Chengdu Vistar Optoelectronics Co., Ltd., Chengdu (CN)

(21) Appl. No.: 18/650,415

(22) Filed: Apr. 30, 2024

Related U.S. Application Data
(63) Continuation of application No. PCT/CN2022/128377, filed on Oct. 28, 2022.

(30) Foreign Application Priority Data
Nov. 25, 2021 (CN) 202111416336.2

(51) Int. Cl. G09G 3/32

(52) U.S. Cl. CPC G09G 3/32; G09G 2300/0452; G09G 2310/0267; G09G 2310/0286

(57) ABSTRACT

A display panel and a display apparatus. The display panel includes: a display area, the display area including a first arrangement area and a second arrangement area disposed in a row direction, a gate driver on array located in the first arrangement area; and a substrate located in the second arrangement area, a light-emitting element located at a side of the substrate, and a pixel circuit connected correspondingly with the light-emitting element, in which an orthographic projection of the light-emitting element on the substrate at least partially does not overlap an orthographic projection of the pixel circuit on the substrate.

### CROSS REFERENCE TO RELATED APPLICATION

The application is a continuation application of International Application No. PCT/CN2022/128377, filed on Oct. 28, 2022, which claims priority to Chinese Patent Application No. 202111416336.2 filed on Nov. 25, 2021, both of which are incorporated herein by reference in their entireties.

### TECHNICAL FIELD

The application relates to the field of display technology, and particularly to a display panel and a display apparatus.

### BACKGROUND

With the development of display technology, the gate driver on array (GOA) is more and more widely used in the field of display technology. The gate driver on array generally includes a plurality of cascaded shift registers, and the progressive scanning drive can be performed for a plurality of rows of pixel units in the display panel through the plurality of shift registers.

### SUMMARY

Embodiments of the application provide a display panel and a display apparatus, which can achieve a frame-less design for the display panel.

In a first aspect, some embodiments of the application provide a display panel, including: a display area, the display area including a first arrangement area and a second arrangement area disposed in a row direction, a gate driver on array located in the first arrangement area; and a substrate located in the second arrangement area, a light-emitting element located at a side of the substrate, and a pixel circuit connected correspondingly with the light-emitting element, in which an orthographic projection of the light-emitting element on the substrate at least partially does not overlap an orthographic projection of the pixel circuit on the substrate.

In a second aspect, some embodiments of the application provide a display apparatus including the display panel according to the first aspect.

In the display panel and the display apparatus according to the embodiments of the application, the display panel includes a display area which includes a first arrangement area and a second arrangement area disposed in a row direction, the first arrangement area includes a gate driver on array; and the second arrangement area includes a substrate, a light-emitting element located at a side of the substrate, and a pixel circuit connected correspondingly with the light-emitting element, in which an orthographic projection of the light-emitting element on the substrate at least partially does not overlap an orthographic projection of the pixel circuit on the substrate. The embodiments of the application achieve a frame-less design for the display panel by compressing the size of the pixel circuit and adjusting the position of the light-emitting element in the row direction, so that the orthographic projection of the compressed pixel circuit on the substrate at least partially does not overlap the orthographic projection of the light-emitting element on the substrate, and thus sufficient space are reserved at the left edge and/or right edge in the display area for arranging the gate driver on array.

### BRIEF DESCRIPTION OF THE DRAWINGS

In order to more clearly illustrate the technical solutions of the embodiments of the application, the accompanying drawings to be used in the embodiments of the application will be briefly described below, and for those of ordinary skill in the art, other accompanying drawings can be obtained based on these drawings without inventive effort.

FIG. 1 shows a schematic structural diagram of a display panel;

FIG. 2 shows a schematic structural diagram of a display panel according to the embodiments of the application;

FIG. 3 shows a cross-sectional view of a local area of a display panel according to the embodiments of the application;

FIG. 4 shows another schematic structural diagram of a display panel according to the embodiments of the application;

FIG. 5 shows yet another schematic structural diagram of a display panel according to the embodiments of the application;

FIG. 6 shows yet another schematic structural diagram of a display panel according to the embodiments of the application;

FIG. 7 shows yet another schematic structural diagram of a display panel according to the embodiments of the application;

FIG. 8 shows yet another schematic structural diagram of a display panel according to the embodiments of the application;

FIG. 9 shows yet another schematic structural diagram of a display panel according to the embodiments of the application;

FIG. 10 shows yet another schematic structural diagram of a display panel according to the embodiments of the application;

FIG. 11 shows yet another schematic structural diagram of a display panel according to the embodiments of the application;

FIG. 12 shows yet another schematic structural diagram of a display panel according to the embodiments of the application;

FIG. 13 shows yet another schematic structural diagram of a display panel according to the embodiments of the application;

FIG. 14 shows yet another schematic structural diagram of a display panel according to the embodiments of the application;

FIG. 15 shows a schematic structural diagram of a display apparatus according to the embodiments of the application.

### DETAILED DESCRIPTION

Features and exemplary embodiments of various aspects of the application will be described in detail below, and in order to make the objects, technical solutions and advantages of the application clearer and more understandable, the application will be described in further detail below in conjunction with the accompanying drawings and specific embodiments.

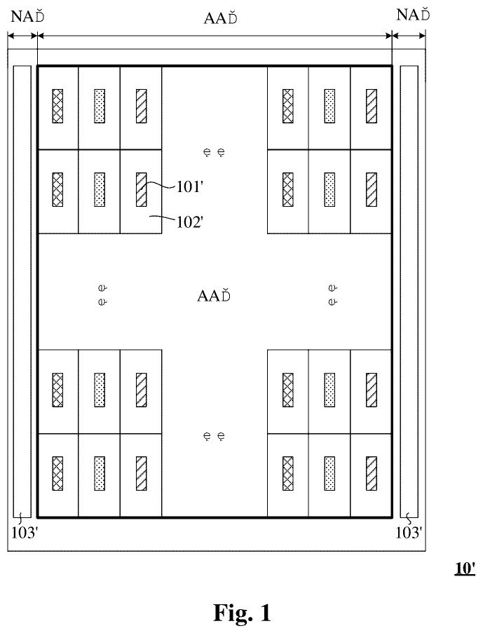

Specifically, as shown in FIG. 1, a display panel 10′ includes a display area AA′ and a non-display area NA′ surrounding the display area AA′. A light-emitting element 101′ and a pixel circuit 102′ are arranged in the display area AA′. The pixel circuit 102′ in FIG. 1 is large, and the orthographic projection of the pixel circuit 102′ on the substrate of the display panel 10′ completely covers the orthographic projection of the light-emitting element 101′ on the substrate of the display panel 10′. As a result, there is not enough space in the display area AA′ for placing a gate driver on array 103′, and the gate driver on array 103′ is generally arranged in the non-display area NA′ located at the left and/or right of the display area AA′, therefore the frame of the display panel 10′ is wide, which is disadvantageous for achieving a narrow-frame or frame-less design for the display panel.

The embodiments of the application provide a display panel and a display apparatus. The technical concept of the embodiments of the application aims to achieve a frame-less design for the display panel by compressing the size of the pixel circuit and adjusting the position of the light-emitting element in the row direction, so that the orthographic projection of the compressed pixel circuit on the substrate at least partially does not overlap the orthographic projection of the light-emitting element on the substrate, and thus sufficient space are reserved at the left edge and/or right edge in the display area for arranging the gate driver on array.

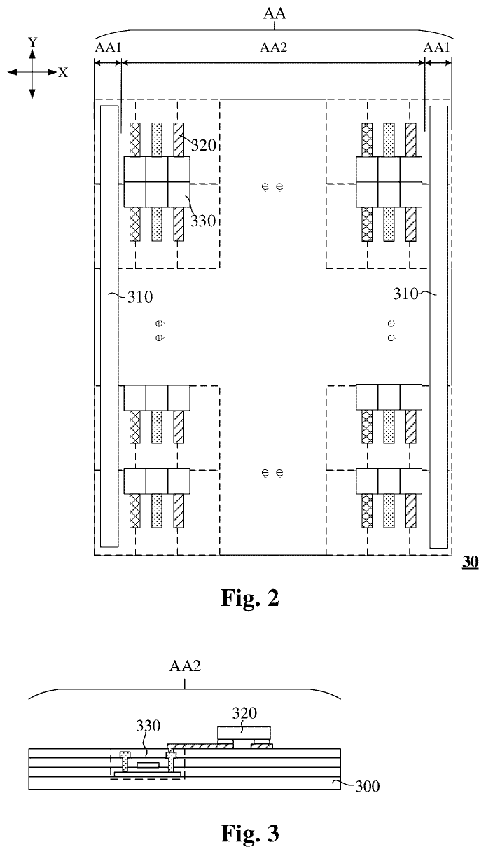

As shown in FIG. 2, a display panel 30 according to the embodiments of the application includes a display area AA which includes a first arrangement area AA1 and a second arrangement area AA2 arranged in a row direction (direction X in FIG. 2), and a gate driver on array 310 is arranged in the first arrangement area AA1. Herein, the gate driver on array 310 may include a plurality of cascaded shift registers which may be arranged in sequence in a column direction (direction Y in FIG. 2), and each of the shift registers may be electrically connected to the gate lines of one or more rows of sub-pixels in the display panel 30 for providing scanning drive signals.

As shown in FIGS. 2 and 3, the second arrangement area AA2 may include a substrate 300, and a light-emitting element 320 and a pixel circuit 330 located at a side of the substrate 300. In the embodiments of the application, for example, the light-emitting element 320 may include a light-emitting diode (LED), a micro light-emitting diode (Micro LED), and a sub-millimeter light-emitting diode (Mini LED). Accordingly, the display panel 30 may include an LED display panel, a Micro LED display panel, and a Mini LED display panel. The pixel circuit 330 in the embodiments of the application is smaller in size, and the orthographic projection of the light-emitting element 320 on the substrate 300 at least partially does not overlap the orthographic projection of the pixel circuit 330 on the substrate 300. Herein, the “at least partially does not overlap” may be understood as only partially overlapping or not overlapping at all. In some specific examples, for example, the orthographic projection of the light-emitting element 320 on the substrate 300 does not overlap the orthographic projection of the pixel circuit 330 on the substrate 300 completely. In this way, it can be avoided that the wirings or devices in the pixel circuit are damaged when the light-emitting element is bound or bonded, and further short circuit can be avoided.

The application achieves a frame-less design for the display panel by compressing the size of the pixel circuit 330, so that the orthographic projection of the compressed pixel circuit 330 on the substrate at least partially does not overlap the orthographic projection of the light-emitting element 320 on the substrate, and thus sufficient space are reserved at the left edge and/or right edge in the display area AA for arranging the gate driver on array 310.

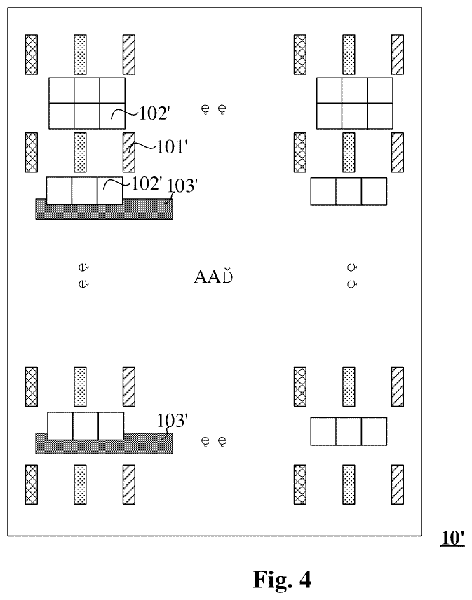

As shown in FIG. 4, if the gate driver on array 103′ is horizontally placed between the adjacent rows of light-emitting elements 101′, in the display panel 10′, the orthographic projection of the gate driver on array 103′ on the substrate of the display panel 10′ will completely overlap the orthographic projection of the pixel circuit 102′ on the substrate of the display panel 10′, and thus the risk of static electricity in the wires of the display panel 10′ will be significantly increased. Moreover, due to the parasitic capacitance formed in the overlapping area between the gate driver on array 103′ and the pixel circuit 102′, the load on the wirings of the pixel circuit will be greatly increased, which affects the display effect of the display panel 10′.

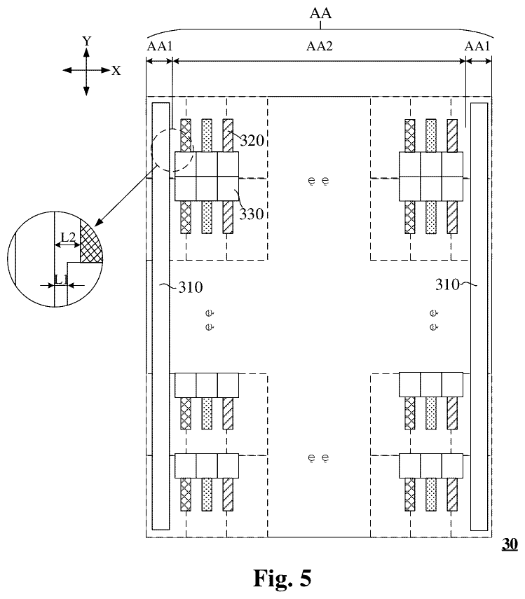

The embodiments of the application propose a solution in which the gate driver on array is vertically arranged at the left edge and/or right edge in the display area. In order to ensure that sufficient space are reserved at the left edge and/or right edge in the display area for arranging the gate driver on array, in some embodiments, the embodiments of the application further adjust the position/arrangement of the light-emitting element. Specifically, as shown in FIG. 5, in the embodiments of the application, both the light-emitting element 320 and the pixel circuit 330 may be arranged in an array. A first spacing L1 in the row direction between an orthographic projection of a first column of the pixel circuit 330 in the second arrangement area AA2 adjacent to the first arrangement area AA1 on the substrate 300 and an orthographic projection of the gate driver on array 310 on the substrate 300 is greater than 0. In the embodiments of the application, the position of the light-emitting element 320 in FIG. 4 is shifted in the row direction toward the center of the display panel 30. After the shifting, a second spacing L2 in the row direction between an orthographic projection of a first column of the light-emitting element 320 in the second arrangement area AA2 adjacent to the first arrangement area AA1 on the substrate 300 and the orthographic projection of the gate driver on array 310 on the substrate 300 is greater than or equal to the first spacing L1, that is, the light-emitting element 320 is located further from the first arrangement area AA1 than the compressed pixel circuit 330.

The application, on the basis of compressing the size of the pixel circuit 330, further adjusts the position of the light-emitting element 320 in the row direction, so that the light-emitting element 320 is further from the first arrangement area (the edge of the display area) than the compressed pixel circuit, therefore the effect of the light-emitting element on the arrangement of the gate driver on array 310 can be avoided, thereby reserving sufficient space at the left edge and/or right edge in the display area AA for arranging the gate driver on array 310, so as to achieve a frame-less design for the display panel.

Compared with the solution in which the gate driver on array is horizontally arranged, the gate driver on array 310 is vertically arranged at the left edge and/or right edge in the display area AA, and the gate driver on array 310 does not overlap the pixel circuit 330 arranged between the adjacent rows of light-emitting elements 320, which can reduce the risk of static electricity in the wires of the display panel and reduce the load on the wirings of the pixel circuit 330, so as to improve the display effect of the display panel.

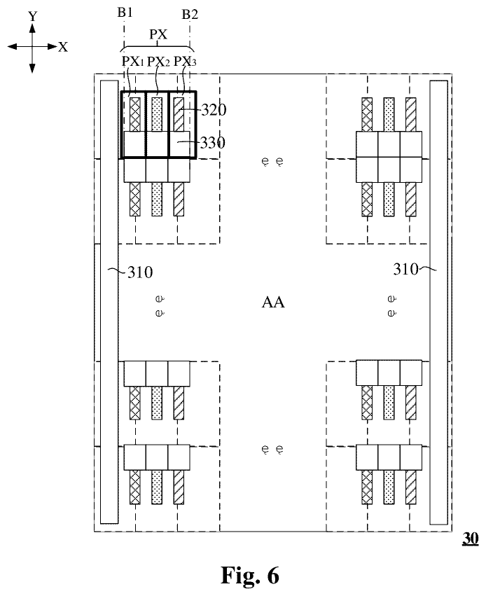

As shown in FIG. 6, according to some embodiments of the application, the display panel 30 may include a plurality of pixel units PX, each of the pixel units PX may include sub-pixels PX1-PXn of a plurality of colors, and n is a positive integer. For any color of the plurality of colors (for example, the j-th color, and j is a positive integer), the sub-pixel PXi of the j-th color may include the light-emitting element 320 of the j-th color and the pixel circuit 330 connected correspondingly with the light-emitting element 320 of the j-th color, and PXi is any one of PX1-PXn. That is, the sub-pixel PXi of each color may be independently driven by a separate pixel circuit 330. For example, for a red sub-pixel, the red sub-pixel may include the light-emitting element 320 emitting red light and the pixel circuit 330 connected correspondingly with the light-emitting element 320 emitting red light. For a green sub-pixel, the green sub-pixel may include the light-emitting element 320 emitting green light and the pixel circuit 330 connected correspondingly with the light-emitting element 320 emitting green light. For a blue sub-pixel, the blue sub-pixel may include the light-emitting element 320 emitting blue light and the pixel circuit 330 connected correspondingly with the light-emitting element 320 emitting blue light.

In the embodiments as shown in FIG. 6, for any i-th pixel unit PX of the plurality of pixel units PX, the light-emitting element 320 and the pixel circuit 330 in the i-th pixel unit PX may be disposed in the column direction (direction Y as shown in FIG. 6), and a plurality of pixel circuits 330 in the i-th pixel unit PX may be sequentially disposed in the row direction (direction X as shown in FIG. 6), and i is a positive integer. A straight line where a left boundary of a leftmost pixel circuit 330 in the i-th pixel unit PX is located is a first boundary line B1, a straight line where a right boundary of a rightmost pixel circuit 330 in the i-th pixel unit PX is located is a second boundary line B2, and a plurality of light-emitting elements 320 in the i-th pixel unit PX may be all located between the first boundary line B1 and the second boundary line B2.

On the basis of compressing the size of the pixel circuit 330, by adjusting the positions of the plurality of light-emitting elements 320 in each pixel unit PX to be between the left boundary of the leftmost pixel circuit and the right boundary of the rightmost pixel circuit in the pixel unit PX, sufficient space can be reserved at the left edge and/or right edge in the display area for arranging the gate driver on array 310, so as to achieve a frame-less design for the display panel.

Reference is still made to FIG. 6, in some specific embodiments, a left boundary of a leftmost light-emitting element 320 in the i-th pixel unit PX and a right boundary of a rightmost light-emitting element 320 in the i-th pixel unit PX may be both located between the first boundary line B1 and the second boundary line B2.

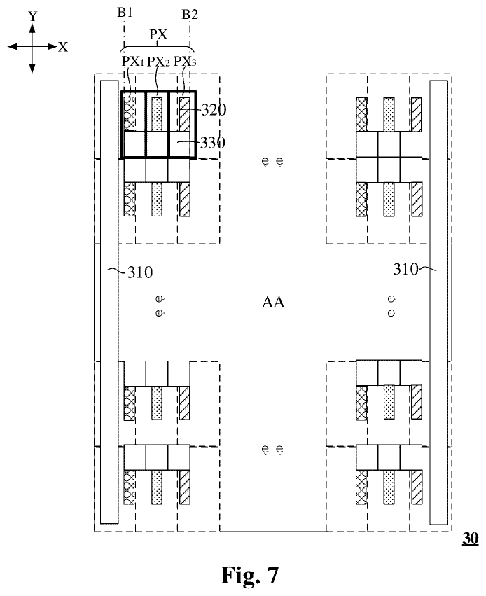

As shown in FIG. 7, in some specific embodiments, the left boundary of the leftmost light-emitting element 320 in the i-th pixel unit PX may be located on the first boundary line B1, and/or the right boundary of the rightmost light-emitting element 320 in the i-th pixel unit PX is located on the second boundary line B2.

In the above implementation, on the basis of compressing the size of the pixel circuit 330, by adjusting the positions of the plurality of light-emitting elements 320 in each pixel unit PX to be between the left boundary of the leftmost pixel circuit and the right boundary of the rightmost pixel circuit in the pixel unit PX, sufficient space can be reserved at the left edge and/or right edge in the display area for arranging the gate driver on array 310, so as to achieve a frame-less design for the display panel.

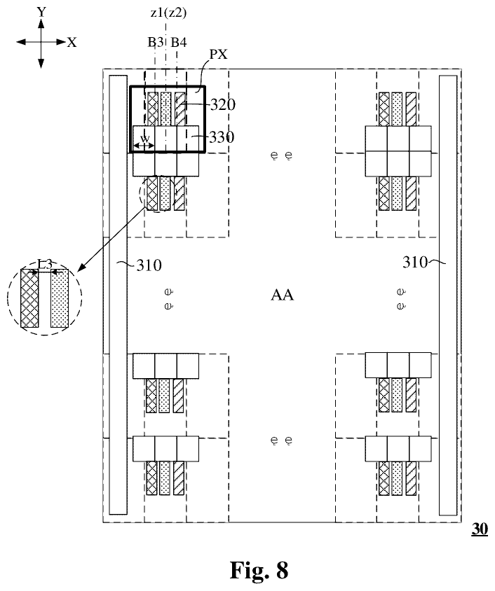

As shown in FIG. 8, in some specific embodiments, for example, each of the pixel units PX may include sub-pixels PX1-PX3 of three colors, i.e., a red sub-pixel, a green sub-pixel, and a blue sub-pixel. That is, each of the pixel units PX may include a light-emitting element emitting red light, a light-emitting element emitting green light, and a light-emitting element emitting blue light, as well as three pixel circuits 330 connected with the light-emitting elements 320 of the three colors. In the embodiments as shown in FIG. 8, for the three pixel circuits 330 in the i-th pixel unit PX, a straight line where a left boundary of the pixel circuit 330 at the middle is located is a third boundary line B3, and a straight line where a right boundary of the pixel circuit 330 at the middle is located is a fourth boundary line B4. For the three light-emitting elements 320 in the i-th pixel unit PX, at least the light-emitting element 320 at the middle is located between the third boundary line B3 and the fourth boundary line B4. In some specific examples, for example, a spacing L3 between the orthographic projections of any two adjacent light-emitting elements 320 in the i-th pixel unit PX on the substrate of the display panel 30 may be reduced to be less than one-half of the width w of one pixel circuit 330 in the row direction, i.e., L3≤w/2.

Specifically, for the three light-emitting elements 320 in the i-th pixel unit PX, at least the light-emitting element 320 at the middle being located between the third boundary line B3 and the fourth boundary line B4 may include the following cases: in each pixel unit PX, the light-emitting elements 320 of the three colors are all located between the third boundary line B3 and the fourth boundary line B4; or in each pixel unit PX, the light-emitting element 320 at the middle and any one of the light-emitting element 320 on the left and the light-emitting element 320 on the right are located between the third boundary line B3 and the fourth boundary line B4; or in each pixel unit PX, only the light-emitting element 320 at the middle is located between the third boundary line B3 and the fourth boundary line B4. Alternatively, in each pixel unit PX, the light-emitting element 320 at the middle and a portion of the light-emitting element 320 on the left and/or a portion of the light-emitting element 320 on the right are located between the third boundary line B3 and the fourth boundary line B4.

In the above implementation, by adjusting the positions of the plurality of light-emitting elements 320 in each pixel unit PX toward the pixel circuit 330 at the middle in the pixel unit PX and reducing the spacing between any two adjacent light-emitting elements 320, sufficient space can be reserved at the left edge and/or right edge in the display area for arranging the gate driver on array, so as to achieve a frame-less design for the display panel.

Reference is still made to FIG. 8, in some specific examples, a midline z1 of an orthographic projection of the pixel circuit 330 at the middle in the i-th pixel unit PX on the substrate of the display panel and a midline z2 of an orthographic projection of the light-emitting element 320 at the middle in the i-th pixel unit PX on the substrate of the display panel are located on a same straight line, and the light-emitting elements 320 on the left and right in the i-th pixel unit PX are symmetrical along the midline z1 (z2). Since the plurality of light-emitting elements 320 in each pixel unit PX are centered and symmetrically arranged, sufficient space can be reserved at the left edge and/or right edge in the display area for arranging the gate driver on array, and also display uniformity can be ensured.

As shown in FIG. 8, by adjusting the positions of the light-emitting elements 320 of the three colors in the pixel unit PX, and for example, by concentrating the light-emitting elements 320 of the three colors, which were originally distributed in three sub-pixel areas, into a single sub-pixel area (dashed box in FIG. 8), sufficient space can be reserved at the left edge and/or right edge in the display area for arranging the gate driver on array.

Reference is still made to FIG. 8, according to some embodiments of the application, a spacing between the orthographic projections of any two adjacent pixel circuits 330 in the i-th pixel unit PX on the substrate of the display panel is 0. That is, in the row direction of the display panel 30, there is no spacing between any two adjacent pixel circuits 330 in each pixel unit PX. By adjusting the spacing between any two adjacent pixel circuits 330 in each pixel unit PX to be 0, any two adjacent pixel circuits 330 are closer to each other, the space occupied by the pixel circuits 330 in the row direction can be reduced, so that more space can be reserved at the left edge and/or right edge in the display area for arranging the gate driver on array, so as to achieve a frame-less design for the display panel.

The arrangement of the light-emitting element 320 and the pixel circuit 330 are described below in conjunction with some embodiments of the application.

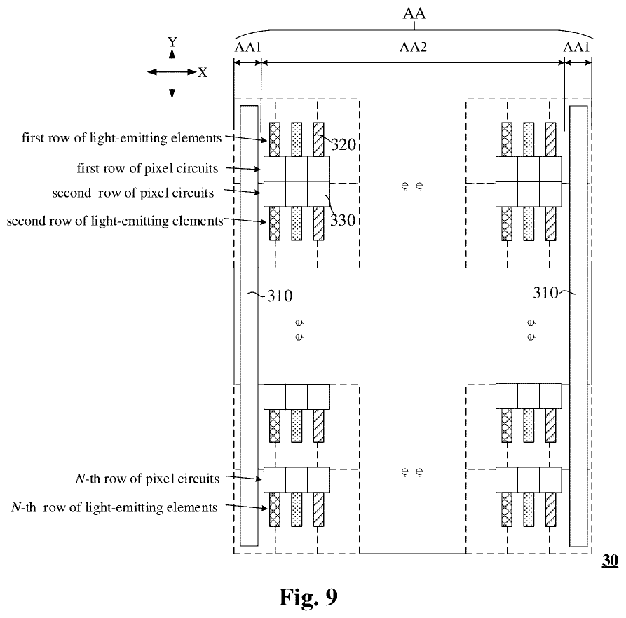

As show in FIG. 9, according to some embodiments of the application, the second arrangement area AA2 may include N rows of the light-emitting elements 320 and N rows of the pixel circuits 330, in which a first row of the pixel circuits 330 may be located at a side of a first row of the light-emitting elements 320 close to a second row of the light-emitting elements 320. Except the first row of the pixel circuits 330, for each row of the pixel circuits 330 (i.e., a j-th row of the pixel circuits 330) in the second to N-th rows of the pixel circuits 330, the j-th row of the pixel circuits 330 may be located at a side of a j-th row of the light-emitting elements 320 close to a (j−1)-th row of the light-emitting elements 320, 2≤j≤N, and j and N are both integers. In the embodiments as shown in FIG. 9, the first row of the pixel circuits 330 are located below the first row of the light-emitting elements 320, while the other rows of the pixel circuits 330 other than the first row of the pixel circuits 330 are all located above the corresponding row of the light-emitting elements 320.

In the above implementation, by arranging the first row of the pixel circuits at a side of the first row of the light-emitting elements close to the second row of the light-emitting elements, i.e., below the first row of the light-emitting elements, on the one hand, it can be ensured that the first row of the pixel circuits will not occupy space in the row direction, and thus sufficient space can be reserved at the left edge and/or right edge in the display area for arranging the gate driver on array, so as to achieve a frame-less design for the display panel; on the other hand, since the space above the first row of the light-emitting elements is limited, the first row of the pixel circuits are arranged below the first row of the light-emitting elements, it can be avoided that the orthographic projection of the first row of the pixel circuits on the substrate of the display panel overlaps the orthographic projection of the first row of the light-emitting elements on the substrate of the display panel, and thus it is avoided that the wirings or devices in the first row of the pixel circuits are damaged when the first row of the light-emitting elements are bound or bonded, and further short circuit are avoided.

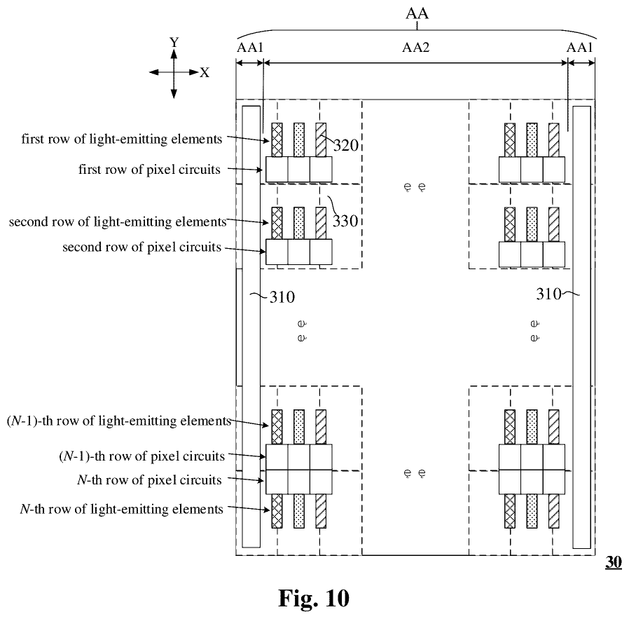

As show in FIG. 10, according to some other embodiments of the application, the second arrangement area AA2 may include N rows of the light-emitting elements 320 and N rows of the pixel circuits 330, in which a N-th row of the pixel circuits 330 may be located at a side of a N-th row of the light-emitting elements 320 close to a (N−1)-th row of the light-emitting elements 320, that is, the last row of the pixel circuits 330 may be located above the last row of the light-emitting elements 320. Except the N-th row of the pixel circuits 330, for each row of the pixel circuits 330 (i.e., a q-th row of the pixel circuits 330) in the first to (N−1)-th rows of the pixel circuits 330, the q-th row of the pixel circuits 330 may be located at a side of a q-th row of the light-emitting elements 320 close to a (q+1)-th row of the light-emitting elements 320, 1≤q≤N−1, and q and N are both integers. In the embodiments as shown in FIG. 10, the last row of the pixel circuits 330 are located above the last row of the light-emitting elements 320, while the other rows of the pixel circuits 330 other than the last row of the pixel circuits 330 are all located below the corresponding row of the light-emitting elements 320.

In the above implementation, by arranging the N-th row of the pixel circuits at a side of the N-th row of the light-emitting elements close to the (N−1)-th row of the light-emitting elements, i.e., above the N-th row of the light-emitting elements, on the one hand, it can be ensured that the N-th row of the pixel circuits will not occupy space in the row direction, and thus sufficient space can be reserved at the left edge and/or right edge in the display area for arranging the gate driver on array, so as to achieve a frame-less design for the display panel; on the other hand, since the space below the N-th row of the light-emitting elements is limited, the N-th row of the pixel circuits are arranged above the N-th row of the light-emitting elements, it can be avoided that the orthographic projection of the N-th row of the pixel circuits on the substrate of the display panel overlaps the orthographic projection of the N-th row of the light-emitting elements on the substrate of the display panel, and thus it is avoided that the wirings or devices in the N-th row of the pixel circuits are damaged when the N-th row of the light-emitting elements are bound, and further short circuit are avoided.

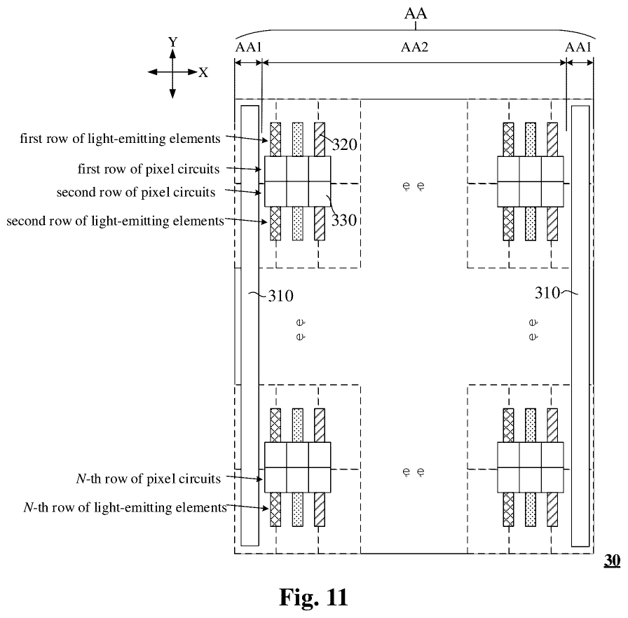

As show in FIG. 11, according to some yet other embodiments of the application, the second arrangement area AA2 may include N rows of the light-emitting elements 320 and N rows of the pixel circuits 330, and each row of the pixel circuits 330 may be located between two adjacent rows of the light-emitting elements 320. For example, a m-th row of the pixel circuits are located at a side of a m-th row of the light-emitting elements close to a (m+1)-th row of the light-emitting elements, and a n-th row of the pixel circuits are located at a side of a n-th row of the light-emitting elements close to a (n−1)-th row of the light-emitting elements, in which m is an odd number and n is an even number. For instance, the first row of the pixel circuits are located at a side of the first row of the light-emitting elements close to the second row of the light-emitting elements, the second row of the pixel circuits are located at a side of the second row of the light-emitting elements close to the first row of the light-emitting elements, the third row of the pixel circuits are located at a side of the third row of the light-emitting elements close to the fourth row of the light-emitting elements, and the fourth row of the pixel circuits are located at a side of the fourth row of the light-emitting elements close to the third row of the light-emitting elements.

In the above implementation, by arranging each row of the pixel circuits between two adjacent rows of the light-emitting elements, on the one hand, it can be ensured that each row of the pixel circuits will not occupy space in the row direction, and thus sufficient space can be reserved at the left edge and/or right edge in the display area for arranging the gate driver on array, so as to achieve a frame-less design for the display panel; on the other hand, it can be avoided that the orthographic projection of the each row of the pixel circuits on the substrate of the display panel overlaps the orthographic projection of each row of the light-emitting elements on the substrate of the display panel, and thus it is avoided that the wirings or devices in the each row of the pixel circuits are damaged when each row of the light-emitting elements are bound, and further short circuit are avoided.

The arrangement of the gate driver on array 310 is described below in conjunction with some embodiments of the application.

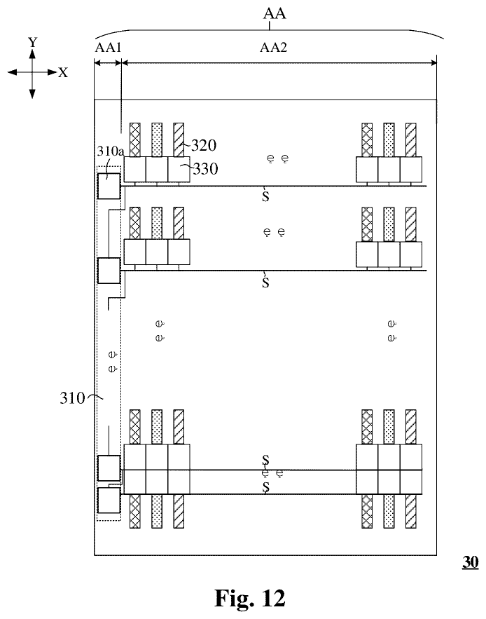

As shown in FIG. 12, according to some embodiments of the application, the first arrangement area AA1 may be located at one side of the second arrangement area AA2. For example, the first arrangement area AA1 may be located on the left or right of the second arrangement area AA2. A gate driver on array 310 may be arranged in the first arrangement area AA1, and the gate driver on array 310 may include N first shift registers 310a, which are distributed in the column direction, i.e., arranged vertically, and N is a positive integer. The display panel 30 may include N rows of the pixel circuits 330 and N scanning lines S (gate lines), in which one scanning line S may be electrically connected with one row of the pixel circuits 330, and the output ends of the N first shift registers 310a may be connected in one-to-one correspondence with the N scanning lines S. The first shift registers 310a may provide scanning signals to the pixel circuits 330 through the scanning lines S, so as to control on/off of transistors in the pixel circuits 330.

In the above implementation, by arranging the gate driver on array in the first arrangement area (e.g., the area at the left edge or the right edge) in the display area AA, a frame-less design and single-side drive can be achieved for the display panel.

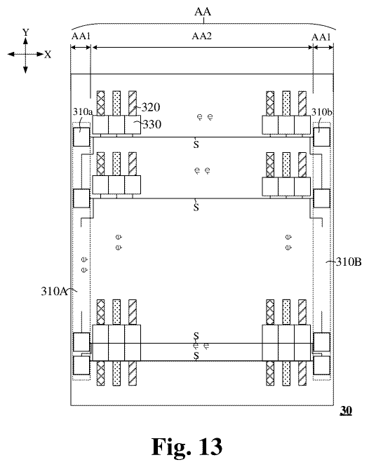

As shown in FIG. 13, which is different from the embodiments as shown in FIG. 12, according to some other embodiments of the application, the first arrangement area AA1 may be located at both sides of the second arrangement area AA2, that is, the first arrangement area AA1 may be located on the left and right of the second arrangement area AA2. A first gate driver on array 310A is arranged in the first arrangement area AA1 at one side, and a second gate driver on array 310B is arranged in the first arrangement area AA1 at the other side. The first gate driver on array 310A may include N first shift registers 310a, which are distributed in the column direction, i.e., arranged vertically, and N is a positive integer. The second gate driver on array 310B may include N second shift registers 310b, which are distributed in the column direction, i.e., arranged vertically.

The display panel 30 may include N rows of the pixel circuits 330 and N scanning lines S, in which one scanning line S may be electrically connected with one row of the pixel circuits 330. The output ends of the N first shift registers 310a may be connected in one-to-one correspondence with the N scanning lines S, and the output ends of the N second shift registers 310b may be connected in one-to-one correspondence with the N scanning lines S. In the embodiments as shown in FIG. 13, the first shift register 310a and the second shift register 310b may provide scanning signals to the pixel circuit 330 through a same scanning line S, so as to control on/off of transistors in the pixel circuit 330, and thus both-sides drive is achieved for the display panel 30.

In the above implementation, by arranging the gate driver on array in the first arrangement area (e.g., the areas at the left edge and the right edge) in the display area AA, a frame-less design and both-sides drive can be achieved for the display panel.

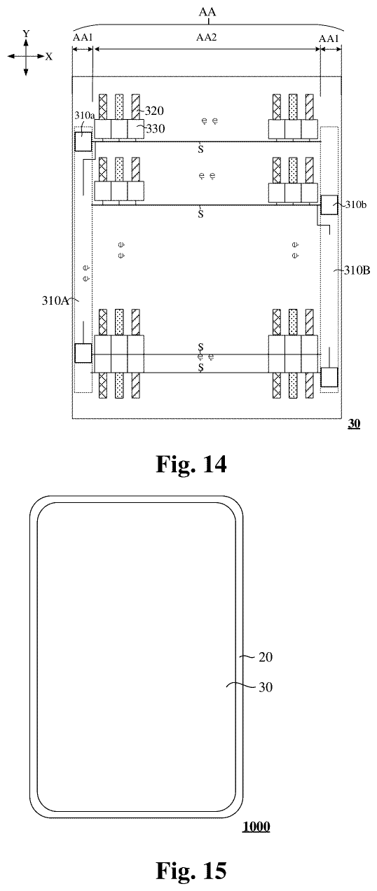

As shown in FIG. 14, which is similar to the embodiments as shown in FIG. 13, according to some yet other embodiments of the application, the first arrangement area AA1 may be located at both sides of the second arrangement area AA2, that is, the first arrangement area AA1 may be located on the left and right of the second arrangement area AA2. A first gate driver on array 310A is arranged in the first arrangement area AA1 at one side, and a second gate driver on array 310B is arranged in the first arrangement area AA1 at the other side. The embodiments as shown in FIG. 14 differ from those as shown in FIG. 13 in that: the first gate driver on array 310A may include Q first shift registers 310a, which are distributed in the column direction, i.e., arranged vertically, in which Q<N and Q is a positive integer; and the second gate driver on array 310B may include N−Q second shift registers 310b, which are distributed in the column direction, i.e., arranged vertically. That is, a sum of the numbers of the first shift registers 310a and the second shift registers 310b in the display panel 30 may be equal to N.

In the embodiments as shown in FIG. 14, the display panel 30 may include N rows of the pixel circuits 330 and N scanning lines S, in which one scanning line S may be electrically connected with one row of the pixel circuits 330. The output ends of the Q first shift registers 310a are connected in one-to-one correspondence with odd-numbered scanning lines S of the N scanning lines S, and the output ends of the N−Q second shift registers 310b are connected in one-to-one correspondence with even-numbered scanning lines S of the N scanning lines S. Alternatively, in some other examples, the output ends of the Q first shift registers 310a are connected in one-to-one correspondence with the even-numbered scanning lines S of the N scanning lines S, and the output ends of the N−Q second shift registers 310b are connected in one-to-one correspondence with the odd-numbered scanning lines S of the N scanning lines S. In the embodiments as shown in FIG. 14, for example, the first shift registers 310a provide scanning signals to the odd-numbered rows of the pixel circuits 330, so as to control on/off of transistors in the odd-numbered rows of the pixel circuits 330; and the second shift registers 310b provide scanning signals to the even-numbered rows of the pixel circuits 330, so as to control on/off of transistors in the even-numbered rows of the pixel circuits 330, and thus cross drive is achieved for the display panel 30.

In the above implementation, by arranging the gate driver on array in the first arrangement area (e.g., the areas at the left edge and the right edge) in the display area AA, a frame-less design and cross drive can be achieved for the display panel.

The application further provides a display apparatus including the display panel according to the above embodiments. As shown in FIG. 15, the display apparatus 1000 includes an apparatus body 20, and the display panel 30 in the above embodiments which covers on the apparatus body 20. The apparatus body 20 may be provided with various types of devices, such as sensor devices, processing devices, and the like, which are not limited herein. The display apparatus 1000 may specifically be an apparatus with display function such as a cell phone, a computer, a tablet computer, a digital camera, a television, an electronic paper, and the like, and is not limited herein.

What is claimed is:

1. A display panel comprising a display area, the display area comprising a first arrangement area and a second arrangement area disposed in a row direction,
a gate driver on array located in the first arrangement area; and
a substrate located in the second arrangement area, a light-emitting element located at a side of the substrate, and a pixel circuit connected correspondingly with the light-emitting element, wherein an orthographic projection of the light-emitting element on the substrate at least partially does not overlap an orthographic projection of the pixel circuit on the substrate.

2. The display panel according to claim 1, wherein a spacing in the row direction between an orthographic projection of a first column of the pixel circuit in the second arrangement area adjacent to the first arrangement area on the substrate and an orthographic projection of the gate driver on array on the substrate is a first spacing, a spacing in the row direction between an orthographic projection of a first column of the light-emitting element in the second arrangement area adjacent to the first arrangement area on the substrate and the orthographic projection of the gate driver on array on the substrate is a second spacing, and the second spacing is greater than or equal to the first spacing.

3. The display panel according to claim 1, wherein the display panel comprises a plurality of pixel units, each of the pixel units comprises sub-pixels of a plurality of colors, the sub-pixel of a j-th color comprises the light-emitting element of the j-th color and the pixel circuit connected correspondingly with the light-emitting element of the j-th color, the j-th color is any color of the plurality of colors, and j is a positive integer; and
for any i-th pixel unit of the plurality of pixel units, a plurality of pixel circuits in the i-th pixel unit are sequentially disposed in the row direction, a straight line where a left boundary of a leftmost pixel circuit in the i-th pixel unit is located is a first boundary line, a straight line where a right boundary of a rightmost pixel circuit in the i-th pixel unit is located is a second boundary line, and a plurality of light-emitting elements in the i-th pixel unit are located between the first boundary line and the second boundary line.

4. The display panel according to claim 3, wherein a left boundary of a leftmost light-emitting element in the i-th pixel unit is located on the first boundary line, and/or a right boundary of a rightmost light-emitting element in the i-th pixel unit is located on the second boundary line.

5. The display panel according to claim 3, wherein a left boundary of a leftmost light-emitting element in the i-th pixel unit and a right boundary of a rightmost light-emitting element in the i-th pixel unit are both located between the first boundary line and the second boundary line.

6. The display panel according to claim 3, wherein each of the pixel units comprises sub-pixels of three colors, and for three pixel circuits in the i-th pixel unit, a straight line where a left boundary of the pixel circuit at the middle is located is a third boundary line, and a straight line where a right boundary of the pixel circuit at the middle is located is a fourth boundary line; and
for three light-emitting elements in the i-th pixel unit, at least the light-emitting element at the middle is located between the third boundary line and the fourth boundary line.

7. The display panel according to claim 6, wherein a midline of an orthographic projection of the pixel circuit at the middle in the i-th pixel unit on the substrate and a midline of an orthographic projection of the light-emitting element at the middle in the i-th pixel unit on the substrate are located on a same straight line, and the light-emitting elements on the left and right in the i-th pixel unit are symmetrical along the midline.

8. The display panel according to claim 3, wherein a spacing between orthographic projections of any two adjacent pixel circuits in the i-th pixel unit on the substrate is 0.

9. The display panel according to claim 3, wherein the second arrangement area comprises N rows of the light-emitting elements and N rows of the pixel circuits, a first row of the pixel circuits are located at a side of a first row of the light-emitting elements close to a second row of the light-emitting elements, and a j-th row of the pixel circuits are located at a side of a j-th row of the light-emitting elements close to a (j−1)-th row of the light-emitting elements, 2≤j≤N, j and N are both integers.

10. The display panel according to claim 3, wherein the second arrangement area comprises N rows of the light-emitting elements and N rows of the pixel circuits, a N-th row of the pixel circuits are located at a side of a N-th row of the light-emitting elements close to a (N−1)-th row of the light-emitting elements, and a q-th row of the pixel circuits are located at a side of a q-th row of the light-emitting elements close to a (q+1)-th row of the light-emitting elements, 1≤q≤N−1, q and N are both integers.

11. The display panel according to claim 3, wherein the second arrangement area comprises N rows of the light-emitting elements and N rows of the pixel circuits, and each row of the pixel circuits are located between two adjacent rows of the light-emitting elements.

12. The display panel according to claim 11, wherein a m-th row of the pixel circuits are located at a side of a m-th row of the light-emitting elements close to a (m+1)-th row of the light-emitting elements, and a n-th row of the pixel circuits are located at a side of a n-th row of the light-emitting elements close to a (n−1)-th row of the light-emitting elements, m is an odd number and n is an even number.

13. The display panel according to claim 1, wherein the first arrangement area is located at one side of the second arrangement area;
the display panel comprises N rows of the pixel circuits and N scanning lines, one scanning line is electrically connected with one row of the pixel circuits, N is a positive integer; and
the gate driver on array comprises N first shift registers, and output ends of the N first shift registers are connected in one-to-one correspondence with the N scanning lines.

14. The display panel according to claim 1, wherein the first arrangement area is located at both sides of the second arrangement area, a first gate driver on array is arranged in the first arrangement area at one side, and a second gate driver on array is arranged in the first arrangement area at the other side; and
the display panel comprises N rows of the pixel circuits and N scanning lines, one scanning line is electrically connected with one row of the pixel circuits, N is a positive integer.

15. The display panel according to claim 14, wherein the first gate driver on array comprises N first shift registers, and output ends of the N first shift registers are connected in one-to-one correspondence with the N scanning lines; the second gate driver on array comprises N second shift registers, and output ends of the N second shift registers are connected in one-to-one correspondence with the N scanning lines.

16. The display panel according to claim 14, wherein the first gate driver on array comprises Q first shift registers, and output ends of the Q first shift registers are connected in one-to-one correspondence with odd-numbered scanning lines of the N scanning lines, Q<N and Q is a positive integer; the second gate driver on array comprises N−Q second shift registers, and output ends of the N−Q second shift registers are connected in one-to-one correspondence with even-numbered scanning lines of the N scanning lines.

17. The display panel according to claim 14, wherein the first gate driver on array comprises Q first shift registers, and output ends of the Q first shift registers are connected in one-to-one correspondence with even-numbered scanning lines of the N scanning lines, Q<N and Q is a positive integer; the second gate driver on array comprises N−Q second shift registers, and output ends of the N−Q second shift registers are connected in one-to-one correspondence with odd-numbered scanning lines of the N scanning lines.

18. The display panel according to claim 1, wherein the orthographic projection of the light-emitting element on the substrate does not overlap the orthographic projection of the pixel circuit on the substrate.

19. The display panel according to claim 3, wherein a spacing between orthographic projections of any two adjacent light-emitting elements in the i-th the pixel unit on the substrate is less than one-half of a width of one of the pixel circuits in the row direction.

20. A display apparatus comprising the display panel according to claim 1.
